(19) United States
(12) Patent Application Publication
(10) Pub. No.: US 2026/0359509 A1
(43) Pub. Date: Nov. 12, 2026

(54) Method for Creating a System Design of a Micro-Electromechanical System

(71) Applicant: Robert Bosch GmbH, Stuttgart (DE)

(72) Inventors: Paul Sebastian Baireuther, Stuttgart (DE); Alexander Buhmann, Reutlingen (DE); Lucia Reeb, Renningen (DE)

(21) Appl. No.: 19/667,900

(22) Filed: May 5, 2026

(30) Foreign Application Priority Data
May 7, 2025 (DE) 10 2025 117 514.4

(51) Int. Cl. G06F 30/17; G06F 30/27

(52) U.S. Cl. CPC G06F 30/17; G06F 30/27

(57) ABSTRACT

A method for creating a system design of a micro-electromechanical system includes (i) defining a planning module by establishing a system message and a language model, (ii) defining a task for the planning module, wherein the system design is to be created according to the task, and wherein at least one technical requirement with respect to the micro-electromechanical system is specified as part of the task, (iii) and creating the system design based on the defined task using the language model. A computer program, a device, and a storage medium for this purpose as well as a micro-electromechanical system are also disclosed.

This application claims priority under 35 U.S.C. § 119 to patent application no. DE 10 2025 117 514.4, filed on May 7, 2025 in Germany, the disclosure of which is incorporated herein by reference in its entirety.

The disclosure relates to a method for creating a system design of a micro-electromechanical system. The disclosure further relates to a computer program, a device, and a storage medium for this purpose as well as to a micro-electromechanical system.

### BACKGROUND

According to the prior art, micro-electromechanical systems are designed manually by experienced system experts. These designs are then also implemented and verified manually in a simulation. However, this is a time-consuming and expensive process.

### SUMMARY

The subject matter of the disclosure is a method, a computer program, a device, and a computer-readable storage medium, as well as a micro-electromechanical system with the features set forth below. Further features and details of the disclosure result from the description and the drawings. Features and details which are described in connection with the method according to the disclosure naturally also apply in connection with the computer program according to the disclosure, the device according to the disclosure, and the computer-readable storage medium according to the disclosure, as well as the micro-electromechanical system according to disclosure, and vice versa in each case, so that a reciprocal reference is always possible with regard to the disclosure of the disclosure.

The subject matter of the disclosure is, in particular, a method for preferably at least partially automated, particularly preferably automated, creation of a system design of a micro-electromechanical system, comprising:
defining a planning module or a planning agent by establishing a system message and, in particular, a large language model,
defining, for example by formulating a prompt for the language model, a task for the planning module, wherein the system design is to be created according to the task, wherein at least one technical requirement with respect to the micro-electromechanical system is specified as part of the task,
creating, for example, by executing the formulated prompt, the system design based on the defined task using the language model.

In particular, the micro-electromechanical system to be designed comprises both micromechanical components and at least one integrated circuit. For example, the at least one technical requirement may specify specific physical properties, such as an operating range, a sensitivity, a type of signal processing, or a specific application of the micro-electromechanical system. It is further conceivable that specifications, in the sense of regulatory or legal guidelines for the micro-electromechanical system, are formulated accordingly and considered within the framework of the at least one technical requirement. Thus, a first system design for the micro-electromechanical system may advantageously be created at least partially automatically, in particular fully automatically, by way of the method according to the disclosure.

In the context of the present disclosure, the terms "AI agent", or "agent" for short, may be used interchangeably and preferably mean the following: a software system that is capable of making decisions and/or executing actions. An action may be, for example, answering a question or creating a plan. When generating actions or decisions, a machine learning model, in particular a large language model and/or a multimodal language model, may be employed. For executing actions, corresponding functions may be made available to the AI agent. For example, the AI agent may be configured to generate and/or execute computer code. In a simple embodiment, an "AI agent" may be provided by a large language model and a system message that may be prepended to any input to the language model. A system message could be, for example: "You are an expert in MEMS system design."

In the context of the present disclosure, the term "system message" is meant in particular to refer to a role description or a general task description that may be used to define an AI agent or a module based on a language model. It may also be understood in particular as contextualization and contain information or examples.

In particular, a system message may be passed to a language model as part of a prompt. The term "prompt" may in particular mean an input to a language model, which may in particular be a request to, for example, generate an output.

It is also optionally conceivable that the method further comprises:
generating a software function for a simulation of at least a part of the created system design, or also the entire created system design, using the language model or another language model, wherein the software function may be generated in, for example, a specified programming language,
simulating the part of the created system design, or also the entire created system design, using the generated software function,
providing a result of the simulation, in particular with respect to the at least one technical requirement.

Furthermore, it is conceivable that the method further comprises:
defining, for example, by way of a corresponding system message and a language model, a verification module and/or verification agent,
wherein verification of the result of the simulation is performed using the verification module. It may in particular be provided that information and/or application or code examples are provided to the agent via its system message. Thus, advantageously, by way of the verification module, a specific perspective for verifying the system design may be provided, which perspective is different from when creating the system design. This allows the verification to be performed more precisely. In the context of the present disclosure, it is also intended in particular that the verification module searches for errors in the system design, analogously to the interaction between coder and code reviewer as known in software development. It is therefore preferably not only a review of the results of the simulation, but in particular a verification of the system design as such. The simulation may be used for requirements that may be calculated by way of simulation.

Furthermore, it is conceivable that the method further comprises:
verifying the created system design and/or a result of the simulation with respect to the at least one technical requirement,
adjusting the created system design based on a result of the verification, wherein it may also be provided that no adjustment is made if the result of the verification indicates that the at least one technical requirement is satisfied.

It may in particular be provided that information and/or application or code examples are made available to the agent via the prompt. Thus, the system design functionality may advantageously be assessed and verified. This may ensure that the at least one technical requirement is also actually implemented by the system design. The process of (simulating), verifying, and adjusting may be repeated several times, in particular until at least one technical requirement is met. The verification may be performed using the provided result of the simulation and/or using the defined verification module.

In addition, it is advantageous for the method to further comprise:
defining an output structure for the system design to be created, wherein the system design is divided into different functional blocks according to the output structure.

This allows a clearer partitioning of the system design to be provided, which may then also be verified more specifically and supplemented with further details. For example, each functional block could include or describe a function, inputs, outputs, and connections to other functional blocks.

For example, it may be provided that the method further comprises:
defining a planning module, and/or a specialized agent, for each of the functional blocks, wherein respective system messages of the defined planning modules of the functional blocks are specific to a respective technical area of the functional blocks and are automatically generated or retrieved from a database, wherein the generation is performed, in particular, based on an analysis of the functional blocks of the created design and/or wherein the generation may involve information from documents or a database, in particular using a RAG system,
modifying the functional blocks using the respective defined system messages.

It is also conceivable, alternatively, that a database or other collection of system messages, and/or various agents, is provided for various technical areas, such as analog-to-digital converters, and for each of the functional blocks a matching system message, and/or agent, is selected from the database and used to modify the functional blocks. By way of the respective system messages, and/or specialized agents, modifications and additions of further details adapted specifically to the functional blocks may advantageously be made, since a perspective from the viewpoint of an expert in the respective field of the functional blocks may be provided.

It is preferably provided within the scope of the disclosure that the method further comprises:
determining specific information regarding the micro-electromechanical system and/or the functional blocks using an information retrieval module.

In other words, a Retrieval-Augmented Generation (RAG) may be performed, wherein generative artificial intelligence (AI) may be combined with external knowledge from a database or information store. This allows expert knowledge to be selectively integrated into the generation process to provide more precise, up-to-date, and contextual responses. RAG can, for example, be used as follows: The information retrieval module may be used to search relevant documents, technical articles, or databases that include expert knowledge. The language model may now use the retrieved knowledge to generate a more precise output. This two-step process may advantageously incorporate specific expert knowledge without the language model having to be pre-trained directly with this knowledge.

Furthermore, the disclosure may provide that defining the task further comprises:
specifying at least one component, in particular an already present component, for the micro-electromechanical system in order to take the at least one component into account during the creation of the system design as a component of the micro-electromechanical system.

Thus, advantageously, the system design may be created taking into account components that are already present or that are desirable for the system design. This allows an individual adjustment to be made to, or restriction to be placed on, the system design.

In another embodiment, the method may further comprise:
deriving requirements for production of the micro-electromechanical system from the created system design.

For example, the requirements may relate to circuit planning on a printed circuit board, mechanical manufacturing, or software-specific requirements, and may advantageously arise directly from the created system design. Thus, a development process for the micro-electromechanical system may be improved and accelerated.

Another object of the disclosure is a computer program, in particular a computer program product, comprising instructions which, when the computer program is executed by at least one computer, cause the computer to carry out the method according to the disclosure. The computer program according to the disclosure thus brings about the same advantages as have been described in detail with reference to the method according to the disclosure.

The subject matter of the disclosure is also a device for data processing that is configured to execute the method according to the disclosure. The device may be at least one computer, for example, that executes the computer program according to the disclosure. The computer may have at least one processor for executing the computer program. A non-volatile data memory may be provided as well, in which the computer program may be stored and from which the computer program may be read by the processor for execution.

The disclosure may also relate to a computer-readable storage medium, which comprises the computer program according to the disclosure and/or commands that, when executed by at least one computer, cause said computer to carry out the method according to the disclosure. The storage medium is configured, for example, as a data memory such as a hard disk and/or a non-volatile memory and/or a memory card. The storage medium may, for example, be integrated in the computer.

A micro-electromechanical system is a further subject matter of the disclosure, wherein the micro-electromechanical system was manufactured using the method according to the disclosure.

Furthermore, the method according to the disclosure may also be executed as a computer-implemented method. Alternatively or additionally, at least one of the disclosed method steps may be computer-implemented and/or performed automatically.

### BRIEF DESCRIPTION OF THE DRAWINGS

Further advantages, features and details of the disclosure will be apparent from the following description, in which exemplary embodiments of the disclosure are described in detail with reference to the drawings. In this case, the features mentioned in the claims and in the description may in each case be essential to the disclosure individually or in any desired combination. It shows:

FIG. 1 a schematic visualization of a method, a micro-electromechanical system with a component, a large language model, a device, a storage medium, and a computer program according to exemplary embodiments of the disclosure.

### DETAILED DESCRIPTION

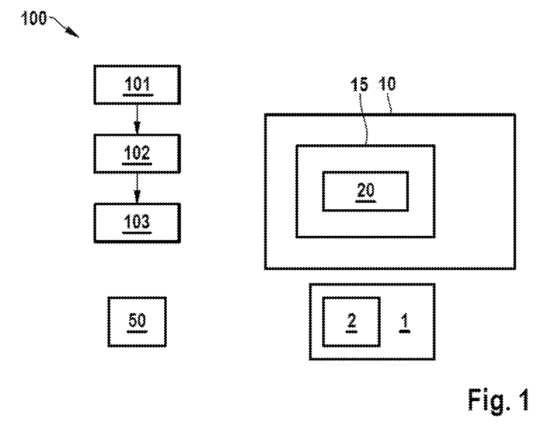

FIG. 1 schematically illustrates a method 100, a micro-electromechanical system 1 with a component 2, a large language model 50, a device 10, a storage medium 15, and a computer program 20 according to exemplary embodiments of the disclosure.

In particular, FIG. 1 shows an exemplary embodiment of a method 100 for creating a system design of a micro-electromechanical system 1. In a first step 101, a planning module is defined by establishing a system message and a language model 50. In a second step 102, a task for the planning module is defined, wherein the system design is to be created according to the task, wherein at least one technical requirement with respect to the micro-electromechanical system 1 is specified as part of the task. In a third step 103, the system design is created based on the defined task using the language model 50.

In accordance with exemplary embodiments of the disclosure, a method of automating the creation of a design of a micro-electromechanical system (MEMS) 1 is provided. The method according to the disclosure is particularly based on the use of a (large) language model 50. In particular, a micro-electromechanical system 1 is designed on a functional level in an automated or partially automated manner and may also be evaluated based on a simulation.

Based on at least one technical requirement, according to exemplary embodiments, the design of the micro-electromechanical system 1 at the system level may be proposed, explained, and tested in a simulation. If the simulation results are promising, the system design may be presented to a user. If not, the system design may be automatically varied and re-evaluated.

According to the disclosure, an agent-based system may be used which includes a large language model 50, a planning module defined by a specified system message, and at least one component expert defined by a system message, in particular one generated automatically. Furthermore, a data processing device may be provided, which is configured to execute code blocks and to design and validate the design of the micro-electromechanical system 1, for example an acceleration sensor.

According to one step, the planning module may be defined by a system message, wherein defining the planning module also comprises, in particular, selecting a (large) language model, for example: "You are an expert in system designs of micro-electromechanical systems specializing in accelerometers. You have extensive knowledge in the simulation of micro-electromechanical systems."

Subsequently, a task may be defined, by way of which the planning module is instructed, while taking into account at least one technical requirement, to create the design for the micro-electromechanical system 1. For example, the task could be defined as follows: "Create a design for a microelectromechanical system for a MEMS accelerometer. Consider the following technical requirements a through f:
a) The accelerometer is intended to have a working range of -3 to 3g, for example for use in a smartphone,
b) The accelerometer is intended to have a sensitivity of at least 64 LSB/g,
c) The signal processing is to be implemented as energy-efficiently as possible,
d) The mechanical unit is intended to be based on a plate capacitor whose capacitance changes under acceleration,
e) No feedback loops are to be used."

Then, optionally, an output structure may be defined and added to the defined task, for example: "Please formulate your response as a succinct list of the following structure:
Functional block 1: Function, inputs, outputs, connections to other functional blocks.
Functional block 2: …”

In the next step, the planning module creates a system plan of interconnected functional blocks. For example, the design may be represented by text and/or graphs and preferably follows the previously defined output structure.

Thereafter, optionally, the planning module may be used to generate, for each of the functional blocks, a system message for a specialized agent of a respective technical area of the functional blocks.

Then, the planning module and/or the specialized agents of the functional blocks may be used to modify the system design so that it meets the technical requirements. Furthermore, a software function for simulating the system design and the functional blocks may be generated. To generate the software function, a software generation module, and/or software generation agent, may be defined by specifying a system message and a language model. It may in particular be provided that information and/or application or code examples are made available to the agent via the prompt.

For example, by way of the planning module, all functional blocks in a circuit may be combined to simulate the combined system design.

Furthermore, a verification of a result of the simulation may be provided. Optionally, a verification module may be defined that may verify the system design, indicating errors in the system design and/or violations of the technical requirements. If errors and/or violations are found, the planning module, or at least one of the specialized agents, may be prompted to modify the affected parts of the system design.

As part of the modification, predefined code blocks (e.g., from Simulink) could be provided to the planning module, and/or the specialized agents, such that only a list of coupled function calls (for example, in text form) needs to be provided instead of executable and/or interpretable computer code. This list preferably follows a previously defined pattern so that it may be translated into executable computer code using a previously defined function.

The agent-based workflow may be automated using open-source frameworks such as AutoGen.

The foregoing explanation of the exemplary embodiments describes the present disclosure exclusively in the context of examples. Of course, individual features of the embodiments may be freely combined with one another, if technically feasible, without leaving the scope of the present disclosure.

What is claimed is:

1. A method for creating a system design of a micro-electromechanical system, comprising:
defining a planning module by establishing a system message and a language model;
defining a task for the planning module, wherein the system design is to be created according to the task, and wherein at least one technical requirement with respect to the micro-electromechanical system is specified as part of the task; and
creating the system design based on the defined task using the language model.

2. The method according to claim 1, further comprising:
generating a software function for a simulation of at least a part of the created system design using the language model or another language model;
simulating the part of the created system design using the generated software function; and
providing a result of the simulation.

3. The method according to claim 1, further comprising:
defining a verification module using a system message and a language model.

4. The method according to claim 1, further comprising:
verifying the system design; and
adjusting the created system design as a function of a result of the verification.

5. The method according to claim 1, further comprising:
generating a software function for a simulation of at least a part of the created system design using the language model or another language model;
simulating the part of the created system design using the generated software function;
providing a result of the simulation;
verifying the system design; and
adjusting the created system design as a function of a result of the verification,
wherein verification is performed using the provided result of the simulation.

6. The method according to claim 1, further comprising:
defining a verification module using a system message and a language model;
verifying the system design; and
adjusting the created system design as a function of a result of the verification,
wherein the verification is performed using the defined verification module.

7. The method according to claim 1, further comprising:
defining an output structure for the system design to be created, wherein the system design is divided into different functional blocks according to the output structure.

8. The method according to claim 7, further comprising:
defining a planning module for each of the functional blocks, wherein the respective system messages of the defined planning modules of the functional blocks are specific to a respective technical area of the functional blocks and are automatically generated or retrieved from a database; and
modifying the functional blocks using the respective defined system messages.

9. The method according to claim 1, further comprising:
determining specific information regarding the micro-electromechanical system and/or the functional blocks using an information retrieval module.

10. The method according to claim 1, wherein defining the task further comprises:
specifying at least one component for the micro-electromechanical system in order to take the at least one component into account during the creation of the system design as a component of the micro-electromechanical system.

11. The method according to claim 1, further comprising:
deriving requirements for production of the micro-electromechanical system from the created system design.

12. A computer program comprising instructions which, when the computer program is executed by at least one computer, prompt the computer to execute the method according to claim 1.

13. A device for data processing configured to carry out the method according to claim 1.

14. A computer-readable storage medium comprising instructions which, when executed by at least one computer, cause the computer to carry out the steps of the method according to claim 1.

15. A micro-electromechanical system, wherein the micro-electromechanical system was produced using the method according to claim 1.
